(19) United States
(12) Patent Application Publication
(10) Pub. No.: US 2011/0114021 A1
(43) Pub. Date: May 19, 2011

(54) PLANAR ANTENNA MEMBER AND PLASMA PROCESSING APPARATUS INCLUDING THE SAME

(76) Inventors: Atsushi Ueda, Hyogo-Ken (JP); Hikaru Adachi, Hyogo-Ken (JP); Caizhong Tian, Hyogo-Ken (JP); Yoshinori Fukuda, Hyogo-Ken (JP); Toshiaki Hongo, Hyogo-Ken (JP); Masao Yoshioka, Hyogo-Ken (JP)

(21) Appl. No.: 12/922,402

(22) PCT Filed: Mar. 13, 2009
(86) PCT No.: PCT/JP2009/054922

§ 371 Date: Dec. 13, 2010

(30) Foreign Application Priority Data
Mar. 14, 2008 (JP) 2008-065635

(51) Int. Cl. C23C 16/50; H01Q 13/10; C23C 8/10

(52) U.S. Cl. 118/723 R; 343/770

(57) ABSTRACT

The present invention is a planar antenna member configured to introduce electromagnetic waves generated by an electromagnetic-wave generating source into a processing vessel of a plasma processing apparatus, the planar antenna member comprising: a base member of a circular plate shape, made of a conductive material; and a plurality of through-holes formed in the base member of a circular plate shape, the through-holes being configured to radiate the electromagnetic waves; wherein: the through-holes include a plurality of first through-holes which are arranged on a circumference of a circle whose center corresponds to a center of the planar antenna member, and a plurality of second through-holes which are arranged concentrically with the circle outside the first through-holes; a ratio L1/r is within a range between 0.35 and 0.5, in which L1 is a distance from the center of the planar antenna member to a center of one of the first through-holes, and r is a radius of the planar antenna member; and a ratio L2/r is within a range between 0.7 and 0.85, in which L2 is a distance from the center of the planar antenna member to a center of one of the second through-holes, and r is the radius of the planar antenna member.

### FIELD OF THE INVENTION

The present invention relates to a planar antenna member used for introducing electromagnetic waves of a predetermined frequency into a processing vessel configured to plasma-process an object to be processed, and a plasma processing apparatus including the planar antenna member.

### BACKGROUND ART

As a plasma processing apparatus configured to perform a plasma process such as an oxidizing process and a nitriding process to an object to be processed such as a semiconductor wafer, there is known a plasma processing apparatus of a type which generates a plasma by introducing microwaves of, e.g., 2.45 GHz frequency into a processing vessel, by using a planar antenna having a plurality of slots (for example, JP11-260594A and JP2001-223171A). Such a microwave plasma processing apparatus can form a surface wave plasma in a chamber, by generating a plasma having a high plasma density.

In the plasma processing apparatus of the above type, when a pressure in the chamber is increased, the plasma density is likely to decrease. When the plasma density decreases, an angular frequency of the plasma becomes smaller than an angular frequency of the 2.45-GHz microwaves, whereby the surface wave plasma cannot be stably maintained. For example, when a plasma process is carried out under a condition where a pressure in the chamber is 133.3 Pa or more, the plasma density may not sufficiently increase. In this case, the surface wave plasma is cut off, so that the surface wave plasma becomes a general bulk plasma.

In order to cope with, e.g., a three-dimensional device process and a micro-fabrication for developing succeeding generation devices, it is necessary to achieve improvement of a process rate and a process uniformity in a wafer plane, under a relatively higher pressure condition that enables a precise process. For this purpose, it is necessary to stably maintain a surface wave plasma without cut-off, by improving controllability of a plasma, even under a relatively higher pressure condition which invites decrease of a plasma density. As one of measures for stably maintaining the surface wave plasma, to decrease the frequency of electromagnetic waves can be considered. For example, with the use of electromagnetic waves having a frequency lower than 2.45 GHz, there is a possibility that the surface wave plasma can be stably maintained even under a relatively higher pressure condition.

However, the structure of a planar antenna for efficiently introducing electromagnetic waves into a chamber differs from frequency to frequency of the electromagnetic waves. A conventional planar antenna (such as a slot pattern) is located and constructed for optimally accomplishing the object of introducing electromagnetic waves of 2.45 GHz frequency into a chamber. Thus, the surface structure (slot pattern) of a planar antenna suited for electromagnetic waves of, e.g., about 1 GHz, which is lower than the conventional microwave frequency, has not been sufficiently examined. First of all, a plasma processing apparatus using electromagnetic waves of lower frequency such as 1 GHz or less is not equipped with a planar antenna itself, because the generation of a surface wave plasma is difficult.

Generally, when a frequency of electromagnetic waves is lowered, a wavelength thereof is elongated. Thus, when electromagnetic waves of about 1 GHz frequency are introduced, it can be considered that a length of a slot and/or an interval between the slots in the planar antenna are/is increased, as compared with a case in which microwaves of 2.45 GHz frequency are introduced. However, even when a planar antenna, which was manufactured based on theoretically calculated length of a slot and layout of the slots, is used to generate a plasma, there is no guarantee that a surface wave plasma is always stably generated. For example, in recent years, the size of a plasma processing apparatus is increased for the process of a 300-mm wafer, and further for the process of a 450-mm wafer. In accordance therewith, the diameter of a planar antenna is also increased. For example, the diameter of a planar antenna for processing a 300-mm wafer is as large as about 500 mm. In a case of a 450-mm wafer, the planar antenna is further enlarged and has a diameter as large as about 600 to 700 mm. In an actual operation of such a large planar antenna, even when the length of a slot and the layout of the slots are set as theoretically optimum values, it is difficult to stably maintain a surface wave plasma.

### SUMMARY OF THE INVENTION

The present invention has been made in view of the above circumstances. The first object of the present invention is to provide a planar antenna capable of efficiently introducing electromagnetic waves having a frequency lower than the conventional microwave frequency, into a chamber. The second object of the present invention is to provide a plasma processing apparatus that uses electromagnetic waves having a frequency lower than the conventional microwave frequency, the plasma processing apparatus having a high controllability over a plasma and being capable of stably generating a surface wave plasma in the chamber, even when a large substrate is processed.

The preset invention is a planar antenna member configured to introduce electromagnetic waves generated by an electromagnetic-wave generating source into a processing vessel of a plasma processing apparatus, the planar antenna member comprising: a base member of a circular plate shape, made of a conductive material; and a plurality of through-holes formed in the base member of a circular plate shape, the through-holes being configured to radiate the electromagnetic waves; wherein: the through-holes include a plurality of first through-holes which are arranged on a circumference of a circle whose center corresponds to a center of the planar antenna member, and a plurality of second through-holes which are arranged concentrically with the circle outside the first through-holes; a ratio L1/r is within a range between 0.35 and 0.5, in which L1 is a distance from the center of the planar antenna member to a center of one of the first through-holes, and r is a radius of the planar antenna member; and a ratio L2/r is within a range between 0.7 and 0.85, in which L2 is a distance from the center of the planar antenna member to a center of one of the second through-holes, and r is the radius of the planar antenna member.

According to the planar antenna member of the present invention, the ratio L1/r is within a range between 0.35 and 0.5, in which L1 is the distance from the center of the planar antenna member to the center of the first through-hole and r is the radius of the planar antenna member. Simultaneously, the ratio L2/r is within a range between 0.7 and 0.85, in which L2 is the distance from the center of the planar antenna member to the center of the second through-hole and r is the radius of the planar antenna member. Thus, even when a frequency of electromagnetic waves generated by a electromagnetic-wave generator is within a range between 800 MHz and 1000 MHz, which is lower than the conventional microwave frequency, generation of reflected waves can be prevented, and thus the electromagnetic waves can be efficiently introduced into a chamber. Thus, a surface wave plasma can be stably maintained in the chamber, and even a larger substrate can be processed.

It is preferable that when there are supposed the following first to third circles, i.e., a first circle passing the centers of the first through-holes with a radius of the first circle being the distance L1, a second circle passing the centers of the second through-holes with a radius of the second circle being the distance L2, and a third circle concentric with the first circle and the second circle, the third circle passing radial mid-points of a circumference of the first circle and a circumference of the second circle, a ratio L3/r is within a range between 0.5 and 0.7, in which L3 is a radius of the third circle and r is the radius of the planar antenna member.

In addition, it is preferable that a ratio (L2−L1)/r is within a range between 0.2 and 0.5, in which (L2−L1) is a difference between the distance L2 and the distance L1, and r is the radius of the planar antenna plate.

In addition, it is preferable that each of the first through-holes and the second through-holes has an elongated shape, and an angle defined by a longitudinal direction of a second through-hole with respect to a longitudinal direction of a corresponding first through-hole is within a range between 85° and 95°. In this case, it is further preferable that an angle defined by a longitudinal direction of a first through-hole with respect to a straight line connecting the center of the planar antenna member and the center of the first through-hole is within a range between 30° and 50°. It is further preferable that an angle defined by a longitudinal direction of a second through-hole with respect to a straight line connecting the center of the planar antenna member and the center of the second through-hole is within a range between 130° and 150°.

In addition, it is preferable that an angle defined between a straight line connecting the center of the planar antenna member and the center of a first through-hole, and a straight line connecting the center of the planar antenna member and the center of a corresponding second through-hole, is within a range between 8° and 15°.

In addition, it is preferable that a frequency of the electromagnetic waves generated by the electromagnetic-wave generating source is within a range between 800 MHz and 1000 MHz.

Alternatively, the present invention is a plasma processing apparatus comprising: a processing vessel configured to contain an object to be processed, the processing vessel being capable of creating a vacuum therein; a gas introduction part configured to supply a gas into the processing vessel; an exhaust apparatus configured to exhaust the processing vessel to reduce a pressure in the processing vessel; a transmission plate hermetically fitted in an upper opening of the processing vessel, the transmission plate being capable of transmitting therethrough electromagnetic waves for generating a plasma into the processing vessel; a planar antenna member disposed above the transmission plate, the planar antenna member being configured to introduce the electromagnetic waves into the processing vessel; a cover member configured to cover the planar antenna member from above; and a waveguide disposed to pass through the cover member, the waveguide being configured to supply the planar antenna member with the electromagnetic waves within a range between 800 MHz and 1000 MHz, which are generated by an electromagnetic-wave generating source; wherein the planar antenna member includes: a planar antenna member configured to introduce electromagnetic waves generated by an electromagnetic-wave generating source into a processing vessel of a plasma processing apparatus, the planar antenna member comprising: a base member of a circular plate shape, made of a conductive material; and a plurality of through-holes formed in the base member of a circular plate shape, the through-holes being configured to radiate the electromagnetic waves; wherein: the through-holes include a plurality of first through-holes which are arranged on a circumference of a circle whose center corresponds to a center of the planar antenna member, and a plurality of second through-holes which are arranged concentrically with the circle outside the first through-holes; a ratio L1/r is within a range between 0.35 and 0.5, in which L1 is a distance from the center of the planar antenna member to a center of one of the first through-holes, and r is a radius of the planar antenna member; and a ratio L2/r is within a range between 0.7 and 0.85, in which L2 is a distance from the center of the planar antenna member to a center of one of the second through-holes, and r is the radius of the planar antenna member.

According to the plasma processing apparatus of the present invention, as compared with a case in which 2.45-GHz microwaves are used, for example, a plasma density equal to or greater than a cut-off density can be maintained even under a higher pressure condition, by setting the frequency of the electromagnetic waves generated by the electromagnetic generating source within a range between 800 MHz and 1000 MHz, which is lower than the conventional microwave frequency. Thus, according to the plasma processing apparatus, even under the relatively higher pressure condition, a sufficient process rate and a sufficient process uniformity in a wafer plane can be achieved, whereby it is possible to cope with a three-dimensional device process and/or a micro-fabrication process, which require a high precision.

Also in the present invention, it is preferable that when there are supposed the following first to third circles, i.e., a first circle passing the centers of the first through-holes with a radius of the first circle being the distance L1, a second circle passing the centers of the second through-holes with a radius of the second circle being the distance L2, and a third circle concentric with the first circle and the second circle, the third circle passing radial mid-points of a circumference of the first circle and a circumference of the second circle, a ratio L3/r is within a range between 0.5 and 0.7, in which L3 is a radius of the third circle and r is the radius of the planar antenna member.

In addition, it is preferable that a ratio (L2−L1)/r is within a range between 0.2 and 0.5, in which (L2−L1) is a difference between the distance L2 and the distance L1, and r is the radius of the planar antenna plate.

In addition, it is preferable that each of the first through-holes and the second through-holes has an elongated shape, and an angle defined by a longitudinal direction of a second through-hole with respect to a longitudinal direction of a corresponding first through-hole is within a range between 85° and 95°. In this case, it is further preferable that an angle defined by a longitudinal direction of a first through-hole with respect to a straight line connecting the center of the planar antenna member and the center of the first through-hole is within a range between 30° and 50°. It is further preferable that an angle defined by a longitudinal direction of a second through-hole with respect to a straight line connecting the center of the planar antenna member and the center of the second through-hole is within a range between 130° and 150°.

In addition, it is preferable that an angle defined between a straight line connecting the center of the planar antenna member and the center of a first through-hole, and a straight line connecting the center of the planar antenna member and the center of a corresponding second through-hole, is within a range between 8° and 15°.

### BRIEF DESCRIPTION OF THE DRAWINGS

FIG. 1 is a schematic sectional view showing a plasma processing apparatus in a first embodiment according to the present invention;

FIG. 2 is a plan view of a main part of a planar antenna plate in the first embodiment according to the present invention;

FIG. 3 is an enlarged view of a slot in the planar antenna plate of FIG. 2;

FIG. 4 is a block diagram showing a schematic structure of a control system of the plasma processing apparatus of FIG. 1;

FIG. 5 is a graph for explaining a pressure dependency model of a plasma cut-off density;

FIG. 6 is a plan view of a main part of a planar antenna plate in a second embodiment according to the present invention;

FIG. 7 is an enlarged view of a slot in the planar antenna plate of FIG. 6; and

FIG. 8 is a plan view of a main part of a planar antenna plate in a third embodiment according to the present invention.

### BEST MODE FOR CARRYING OUT THE INVENTION

### First Embodiment

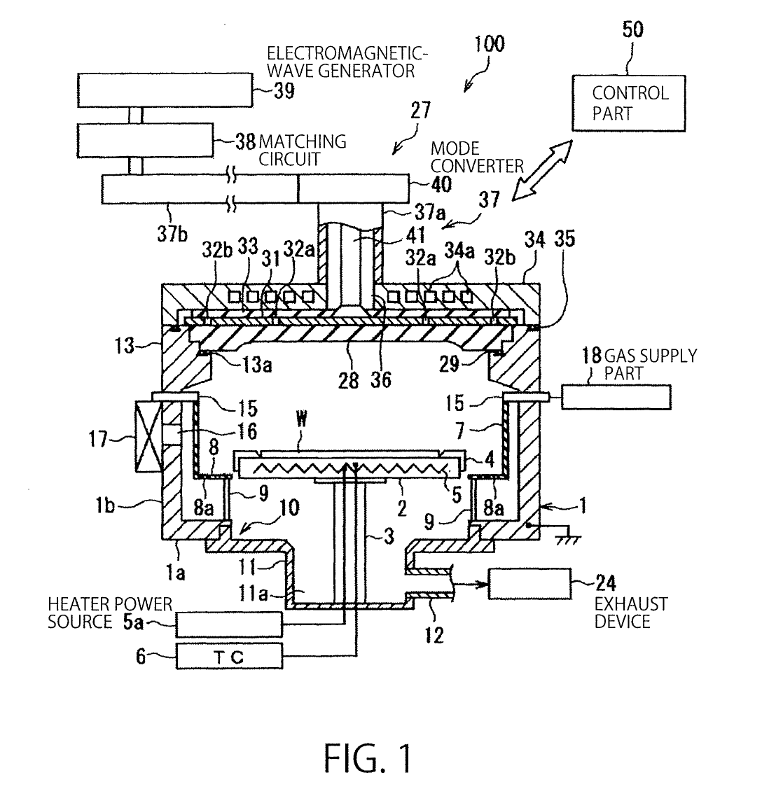

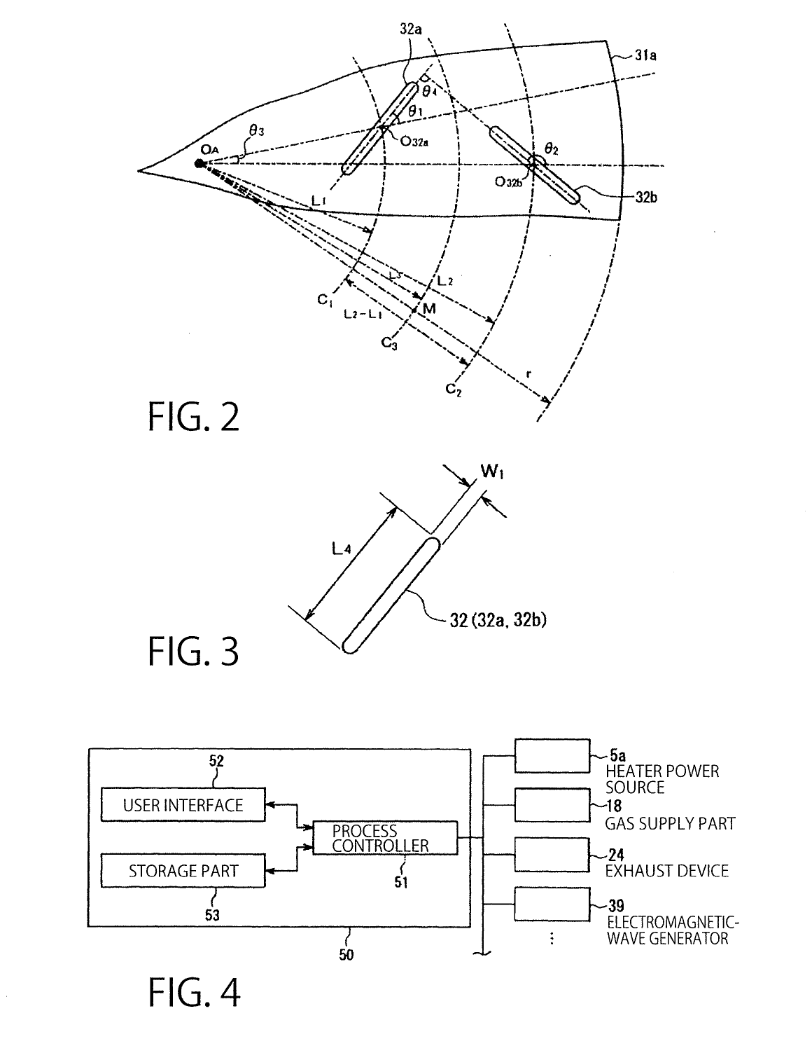

Embodiments of the present invention will be described in detail below with reference to the drawings. FIG. 1 is a sectional view schematically showing a plasma processing apparatus 100 in a first embodiment according to the present invention. FIG. 2 is a plan view of a main part of a planar antenna plate (planar antenna member) in the first embodiment according to the present invention, which is used in the plasma processing apparatus 100 of FIG. 1. FIG. 3 is an enlarged view of a slot as a through-hole in the planar antenna plate. FIG. 4 is a block diagram showing an example of a schematic structure of a control system in the plasma processing apparatus 100 of FIG. 1.

The plasma processing apparatus 100 is constructed as a plasma processing apparatus configured to generate a plasma of a high density and a low electron temperature, by introducing electromagnetic waves into a processing vessel, by means of a planar antenna plate having a plurality of slot-like through-holes, in particular, an RLSA (Radial Line Slot Antenna), so as to generate a plasma. In the plasma processing apparatus 100, it is possible to perform a process by a plasma having a plasma density of 10¹⁰/cm³ to 10¹³/cm³ and an electron temperature as low as 0.5 to 2 eV or below. Thus, the plasma processing apparatus 100 can be suitably used in manufacturing processes of various semiconductor devices.

The plasma processing apparatus 100 mainly includes: a hermetically sealable chamber (processing vessel) 1; a gas supply part 18 configured to supply a gas into the chamber 1; an exhaust apparatus 24 configured to exhaust the chamber 1 to reduce a pressure in the chamber 1; an electromagnetic-wave introduction part 27 disposed above the chamber 1, and configured to introduce electromagnetic waves into the chamber 1; a planar antenna plate 31; and a control part 50 configured to control the respective components of the plasma processing apparatus 100. The gas supply part 18, the exhaust apparatus 24, and the electromagnetic-wave introduction part 27 constitute plasma generating means for generating a plasma in the chamber 1.

The chamber 1 is formed of a substantially cylindrical vessel that is grounded. Alternatively, the chamber 1 may be formed of a quadrangular cylindrical vessel. The chamber 1 has a bottom wall 1a and a side wall 1b which are made of metal material such as aluminum.

Inside the chamber 1, there is disposed a stage 2 configured to horizontally support a silicon wafer (hereinafter referred to simply as “wafer”) W as an object to be processed. The stage 2 is made of a material of a high thermal conductivity, e.g., ceramics such as AlN. The stage 2 is supported by a cylindrical support member 3 extending upward from a center bottom part of an exhaust chamber 11. The support member 3 is made of ceramics such as AlN.

The stage 2 is provided with a cover ring 4 for covering an outer peripheral edge of the stage 2 and for guiding the wafer W. The cover ring 4 is an annular member made of quartz, AlN, Al₂O₃, or SiN, for example. Alternatively, the cover ring 4 may be disposed so as to cover all the surface of the stage 2.

Embedded in the stage 2 is a heater 5 of a resistance heating type serving as a temperature adjusting mechanism. The heater 5 is fed by a heater power source 5a to heat the stage 2, so that the wafer W as an object to be processed can be uniformly heated.

The stage 2 is provided with a thermocouple (TC) 6. Since a temperature is measured by the thermocouple 6, the heating temperature of the wafer W can be controlled within a range from, for example, a room temperature to 900° C.

The stage 2 has wafer support pins (not shown), which can move upward and downward the wafer W while supporting the same. Each wafer support pin is disposed so as to be projectable and retractable with respect to the surface of the stage 2.

A cylindrical quartz liner 7 is disposed on an inner circumference of the chamber 1. In addition, a quartz baffle plate 8, which has a number of exhaust ports 8a, is annularly disposed on an outer circumferential side of the stage 2, whereby the chamber 1 can be uniformly exhausted. The baffle plate 8 is supported by a plurality of support columns 9. When the plasma processing apparatus 100 is used as a plasma CVD apparatus, the liner 7 and the baffle plate 8 may be omitted.

An opening 10 for discharging an atmosphere in the chamber 1 is formed in a substantially central portion of the bottom wall 1a of the chamber 1. The downwardly projecting exhaust chamber 11 is disposed to cover the opening 10 and to communicates with the same. An exhaust pipe 12 is connected to the exhaust chamber 11, and the exhaust apparatus 24 is connected to the exhaust pipe 12, whereby the chamber 1 can be uniformly exhausted.

An upper opening of the chamber 1 is provided with an annular lid frame (lid) 13 configured to open and close the chamber 1. An inner circumferential part of the lid frame 13 projects inward (into the space of the chamber) so as to form an annular support part 13a for supporting thereon a transmission plate 28.

A gas introduction part 15 is disposed on an upper portion (side wall 1b) of the chamber 1. The gas introduction part 15 is connected to a gas introduction part 18 for supplying process gases (an oxygen-containing gas and a plasma exciting gas) through a gas pipe. The gas introduction part 15 may have a nozzle shape projecting into the chamber 1, or a shower-head shape having a plurality of gas apertures.

The side wall 1b of the chamber 1 is provided with a loading and unloading port 16 and a gate valve 17 configured to open and close the loading and unloading port 16, so that through the loading and unloading port 16, the wafer W can be transferred between the plasma processing apparatus 100 and a transfer chamber (not shown) adjacent thereto.

The gas introduction part 18 has gas supply sources (not shown) respectively configured to supply process gases such as an inert gas for exciting a plasma such as Ar, Kr, Xe, or He, an oxidizing gas such as an oxygen-containing gas used in an oxidizing process, a nitrogen-containing gas used in a nitriding process, and a film deposition gas. When a CVD process is carried out, there may be also disposed gas supply sources respectively configured to supply a material gas, a purge gas such as N₂ and Ar used for substituting the atmosphere in the chamber, and a cleaning gas such as ClF₃ and NF₃ used for cleaning the inside of the chamber 1. The respective gas supply sources are provided with mass-flow controllers and opening and closing valves, not shown, whereby the gases to be supplied can be switched and/or flow rates thereof can be controlled.

The exhaust apparatus 24 has a high-speed vacuum pump such as a turbo molecular pump. As described above, the exhaust apparatus 24 is connected to the exhaust chamber 11 of the chamber 1 through the exhaust pipe 12. When the exhaust apparatus 24 is actuated, the gas in the chamber 1 uniformly flows into a space 11a of the exhaust chamber 11, and is then discharged outside from the space 11a through the exhaust pipe 12. Thus, the pressure inside the chamber 1 can be rapidly reduced to, e.g., 0.133 Pa.

Next, the structure of the electromagnetic-wave introduction part 27 is described. The electromagnetic-wave introduction part 27 mainly includes the transmission plate 28, the planar antenna plate 31, a slow-wave plate 33, a cover member 34, a waveguide 37, a matching circuit 38, and an electromagnetic-wave generator 39.

The transmission plate 28 through which electromagnetic waves can be transmitted is provided on the inwardly-extending support part 13a of the lid frame 13. The transmission plate 28 is made of a dielectric material such as quartz or ceramics such as Al₂O₃ or AlN. A gap between the transmission plate 28 and the support part 13a is hermetically sealed by a sealing member 29. Thus, the inside of the chamber 1 can be hermetically held.

The planar antenna plate 31 is disposed above the transmission plate 28 such that the planar antenna plate 31 is opposed to the stage 2. The planar antenna plate 31 has a circular plate shape. However, not limited to the circular plate shape, the planar antenna plate 31 may have a quadrangular plate shape, for example. The planar antenna plate 31 is locked on an upper end of the lid frame 13 and is grounded.

As shown in FIGS. 2 and 3, for example, the planar antenna plate 31 has a base member 31a of a circular plate shape, and a lot of pairs of slots 32 (32a and 32b) formed in the base member 31a with a predetermined pattern. The base member 31a is formed of a conductive plate such as a gold-plated or silver-plated copper plate, an aluminum plate, or a nickel plate. Each slot 32 functioning as an electromagnetic-wave radiation hole has an elongated shape. Since an abnormal discharge is likely to occur in corner portions of the slot 32, the corner portions on opposed ends of the elongated slot 32 are rounded. The slots 32 include: a plurality of first slots 32a which are arranged on a circumference of a circle whose center corresponds to a center O_{A} of the planar antenna plate 31; and a plurality of second slots 32b arranged outside the first slots 32a so as to surround the same. The first slots 32a and the second slots 32b are concentrically arranged to form pairs. The arrangement of the slots 32 in the planar antenna plate 31 will be described in detail below.

The slow-wave plate 33, which is made of a material having a dielectric constant larger than vacuum, is disposed above the planar antenna plate 31. The slow-wave plate 33 is disposed to cover the planar antenna plate 31. The material of the slow-wave plate 33 may be quartz, a polytetrafluoroethylene resin, or a polyimide resin, for example. In consideration that a wavelength of electromagnetic waves is elongated in vacuum, the slow-wave plate 33 has a function for reducing the wavelength of the electromagnetic waves so as to adjust a plasma.

The planar antenna plate 31 and the transmission plate 28, and the slow-wave plate 33 and the planar antenna plate 31, may either be in contact with each other or separated from each other. However, in terms of restraining generation of standing waves, these plates are preferably in contact with each other.

Disposed above the chamber 1 is the cover member 34 made of a conductive material so as to cover the planar antenna plate 31 and the slow-wave plate 33. The cover member 34 also has a function for defining a waveguide path. The cover member 34 is made of a conductive metal material such as aluminum, stainless steel, or copper. In order to prevent leakage of electromagnetic waves to the outside, a gap between the upper end of the lid frame 13 and the cover member 34 is sealed by a sealing member 35 such as a conductive spiral shield ring. In addition, the cover member 34 has a cooling-water channel 34a. When a cooling water circulates through the cooling-water channel 34a, the cover member 34, the slow-wave plate 33, the planar antenna plate 31, the transmission plate 28, and the lid frame 13 can be cooled. Due to this cooling mechanism, the cover member 34, the slow-wave plate 33, the planar antenna plate 31, the transmission plate 28, and the lid frame 13 can be prevented from being thermally deformed and/or damaged. The lid frame 13, the planar antenna plate 31, and the cover member 34 are grounded.

An opening 36 is formed in a center of an upper wall (ceiling part) of the cover member 34. A lower end of the waveguide 37 is connected to the opening 36. The electromagnetic-wave generator 39 for generating electromagnetic waves is connected to the other end of the waveguide 37 through a matching circuit 38. A frequency of the electromagnetic waves generated by the electromagnetic-wave generator 39 is preferably within a range between, e.g., 800 MHz to 1000 MHz, which is lower than the conventional microwave frequency, for the reason as described below. In particular, 915 MHz is preferred.

The waveguide 37 has a coaxial waveguide 37a having a circular cross-section and extending upward from the opening 36 of the cover member 34, and a rectangular waveguide 37b connected to an upper end of the coaxial waveguide 37a via a mode converter 40. The mode converter 40 has a function for converting a TE mode of the electromagnetic waves propagating in the rectangular waveguide 37b into a TEM mode.

An inner conductive member 41 extends through a center of the coaxial waveguide 37a. A lower end of the inner conductive member 41 is fixedly connected to a center of the planer antenna plate 31. Owing to this structure, the electromagnetic waves can be efficiently, uniformly propagated into the planar antenna plate 31 in a radial direction thereof, through the inner conductive member 41 of the coaxial waveguide 37a.

By means of the electromagnetic-wave introduction mechanism 27 as structured above, the electromagnetic waves generated by the electromagnetic-wave generator 39 are transmitted to the planar antenna plate 31 through the waveguide 37, and are then introduced into the chamber 1 through the transmission plate 28.

The respective components of the plasma processing apparatus 100 are connected to the control part 50 so as to be controlled by the control part 50. As shown in FIG. 4, the control part 50 includes a process controller 51 having a CPU, a user interface 52 connected to the process controller 51, and a storage part 53. The process controller 51 is a control unit in the plasma processing apparatus 100, which is configured to totally control the respective components (e.g., the heater power source 5a, the gas introduction part 18, the exhaust apparatus 24, the electromagnetic-wave generator 39, and so on) in relation to process conditions such as a temperature, a gas flow rate, a pressure, and an output of electromagnetic waves.

The user interface 52 has a keyboard by which a process manager can input commands for managing the plasma processing apparatus 100, and a display for visualizing a working state of the plasma processing apparatus 100. The storage part 53 stores a control program (software) for realizing various processes to be carried out by the plasma processing apparatus 100 under the control of the process controller 51, and recipes in which process condition data are recorded.

According to need, a given recipe is called from the storage part 53 and executed by the process controller 51 based on an instruction command from the user interface 52, and then a desired process is performed in the chamber 1 of the plasma processing apparatus 100 under the control of the process controller 51. It is possible to use the control program and the recipes of the process condition data which are stored in a computer-readable storage medium, such as a CD-ROM, a hard disc, a flexible disc, a flash memory, a DVD, or a blu-ray disc. It is also possible to use the control program and the recipes which are occasionally transmitted from another apparatus through a leased line, for example.

In the plasma processing apparatus 100 as structured above, even when a plasma is generated directly on a substrate under a temperature of as low as 800° C. or below, a plasma process can be carried out without damaging a base film or the like. In addition, the plasma processing apparatus 100 is excellent in generating a uniform plasma, and thus a substrate of a large diameter can be uniformly processed.

With reference again to FIGS. 2 and 3, the arrangement of the slots 32 in the planar antenna plate 31 is described. In the plasma processing apparatus 100, for example, 915-MHz electromagnetic waves generated by the electromagnetic-wave generator 39 are supplied to the central part of the planar antenna plate 31 through the coaxial waveguide 37a, and are radially propagated in the flat waveguide path defined by the planar antenna plate 31 and the cover member 34. Due to the provision of the slots 32 in the course of the propagation route, the electromagnetic waves can be uniformly, efficiently radiated into the space of the lower chamber 1 from the openings of the slots 32. In this embodiment, for example, sixteen first slots 32a are arranged at regular intervals in the circumferential direction of the planar antenna plate 31. Similarly, sixteen second slots 32b as counterparts of the first slots 32a are arranged at regular intervals in the circumferential direction of the planar antenna plate 31.

With a view to restraining generation of reflected waves and improving an introduction efficiency of the electromagnetic waves into the chamber 1, a ratio L1/r is within a range between 0.35 and 0.5, in which L1 is a distance from the center O_{A} of the planar antenna plate 31 (which is the same as the center of the base member 31a) to a center O₃₂ₐ of one of the first slots 32a, and r is a radius of the planar antenna plate 31. It was confirmed that, when the ratio L1/r falls below 0.35 or exceeds 0.5, a power efficiency in the introduction of the electromagnetic waves from the respective slots is impaired.

In addition, a ratio L2/r is within a range between 0.7 and 0.85, in which L2 is a distance from the center O_{A} of the planar antenna plate 31 to a center O_{32b} of one of the second slots 32b, and r is the radius of the planar antenna plate 31. It was confirmed that, when the ratio L1/r falls below 0.7 or exceeds 0.85, a power efficiency in the introduction of the electromagnetic waves from the respective slots is impaired.

The ratio L1/r between the distance L1 and the radius r and the ratio L2/r between the distance L2 and the radius r can be determined to some degree depending on a wavelength λg of the electromagnetic waves which has been adjusted by the slow-wave plate 33. However, a calculated value and an actually effective range are not always conformable to each other. Under the circumstances, the present inventors have found that the ratio L1/r within the above range and the ratio L2/r within the above range are effective.

Then, the following circles C1 to C3 are supposed. Namely, the circle C1 is concentric with the planar antenna plate 31 and passes the centers O₃₂ₐ of the first slots 32a, with a radius of the circle C1 being the distance L1. The circle C2 is concentric with the planar antenna plate 31 and passes the centers O_{32b} of the second slots 32b, with a radius of the circle C2 being the distance L2. The circle C3 is concentric with the planar antenna plate 31, and has a radius which is a distance L3 extending from the center O_{A} of the planar antenna plate 31 to radial mid-points M between circumferences of the circles C1 and C2. In this case, in terms of improving the introduction efficiency (power efficiency) of the electromagnetic waves into the chamber 1, it was confirmed that a ratio L3/r is preferably within a range between 0.5 and 0.7, in which L3 is the above-described distance and r is the radius of the planar antenna plate 31. By specifying the ratio L3/r within the above range, it was confirmed that generation of reflected waves can be restrained, and that the electromagnetic waves can be efficiently supplied into the chamber 1 so as to generate a stable plasma with a high power efficiency.

In addition, in terms of improving the introduction efficiency (power efficiency) of the electromagnetic waves into the chamber 1, it was confirmed that a ratio (L2−L1)/r is preferably within a range between 0.2 and 0.5, in which (L2−L1) is a difference between the distance L2 and the distance L1, and r is the radius of the planar antenna plate 31. By setting the ratio (L2−L1)/r within the above range, it was confirmed that generation of reflected waves can be restrained, and that the electromagnetic waves can be efficiently supplied into the chamber 1 so as to generate a stable plasma with a high power efficiency.

The “radius r of the planar antenna plate 31” means a radius of a circular area which can efficiently function as a planar antenna on the base member 31a. For example, when the planar antenna member 31 is fastened on the upper end of the lid frame 13 by fastening means such as screws, the base member 31a should have, at a peripheral part thereof, an engagement area (not shown, with a width of about 3 to 20 mm from the peripheral edge of the base member 31a) having screw holes. The engagement area provided for fastening the planar antenna plate 31 is a portion that does not function as the antenna. Thus, the radius r of the planar antenna 31 is specified (recognized) so as not to include the engagement area.

Next, arrangement angles of the slots 32 in the planar antenna plate 31 are described. By means of the electromagnetic waves propagated from the coaxial waveguide 37a to the center of the planar antenna plate 31, a surface current is generated on the base member 31a of the planar antenna plate 31 made of a conductive material. The surface current, which will flow radially outward the planar antenna plate 31, is interrupted by the slots 32 in the course of the flowing. Then, an electric charge is induced along the edge of each slot 32. The thus induced electric charge generates an electromagnetic field. The electromagnetic field is radiated toward the space inside the lower chamber 1 through the slots 32 and the transmission plate 28. Thus, when a longitudinal direction of the slot 32 conforms to a direction of the surface current (radial direction of the planar antenna plate 31), the radiation of the electromagnetic field into the chamber 1 is difficult to occur.

Thus, in order to uniformly and efficiently introduce the electromagnetic field into the chamber 1, arrangement angles of the slots 32 are important factors. In this embodiment, an angle θ1 defined by the longitudinal direction of a first slot 32a with respect to a straight line connecting the center O_{A} of the planar antenna plate 31 and the center O₃₂ₐ of the first slot 32a is preferably within a range between 30° and 50°. By specifying the angle θ1 within the range between 30° and 50°, it was confirmed that generation of reflected waves can be restrained, and that the electromagnetic waves can be efficiently supplied into the chamber 1 so as to generate a stable plasma. When the angle θ1 falls below 30°, an efficiency of the waves propagating in the radial direction of the planar antenna plate 31 is impaired. Meanwhile, when the θ1 exceeds 50°, an efficiency of the waves propagating in the circumferential direction of the planar antenna plate 31 is impaired.

For the same reason as described above, an angle θ2 defined by the longitudinal direction of a second slot 32b with respect to a straight line connecting the center O_{A} of the planar antenna plate 31 and the center O_{32b} of the second slot 32b is preferably within a range between 130° and 150°. By specifying the angle θ2 within the range between 130° and 150°, it was confirmed that generation of reflected waves can be restrained, and that the electromagnetic waves can be efficiently supplied into the chamber 1 so as to generate a stable plasma with a high power efficiency. When the angle θ2 falls below 130°, an efficiency of the waves propagating in the circumferential direction of the planar antenna plate 31 is impaired. Meanwhile, when the θ2 exceeds 150°, an efficiency of the waves propagating in the radial direction of the planar antenna plate 31 is impaired.

In addition, an angle θ3 defined between the straight line connecting the center O_{A} of the planar antenna plate 31 and the center O₃₂ₐ of a first slot 32a, and the straight line connecting the center O_{A} of the planar antenna plate 31 and the center O_{32b} of a corresponding second slot 32b, is preferably within a range between 8° and 15°. By specifying the angle θ3 within the range between 8° and 15°, it was confirmed that generation of reflected waves can be restrained, and that the electromagnetic waves can be efficiently supplied into the chamber 1 so as to generate a stable plasma with a high power efficiency. When the angle θ3 is deviated from the above range, a radiation efficiency of the electromagnetic waves from the slots is impaired.

In addition, an angle θ4 defined between the longitudinal direction of a first slot 32a and the longitudinal direction of a corresponding second slot 32b is preferably a substantially right angle, and may be within a range between 85° and 95°, for example.

As described above, by suitably adjusting the respective angles θ1, θ2, θ3 and θ4, the electromagnetic field can be uniformly introduced into the chamber 1 through the slots 32 with a high efficiency. An angle defined between two straight lines extending from the center O_{A} of the planar antenna plate 31 to the centers O₃₂ₐ of the adjacent first slots 32a can be set suitably, e.g., equally according to the number of the first slots 32a. Similarly, an angle defined between two straight lines extending from the center O_{A} of the planar antenna plate 31 to the centers O_{32b} of the adjacent second slots 32b can be set suitably, e.g., equally according to the number of the second slots 32b.

As shown in FIG. 3, a length of each first slot 32a and a length of each second slot 32b are the same with each other (slot length L4). In addition, a width of each first slot 32a and a width of each second slot 32b are the same with each other (slot width W1). A ratio (L4/W1) between the slot length and the slot width is preferably within a range between 1 and 26, in terms of improving a radiation efficiency (power efficiency of the introduction of the electromagnetic waves). The slot length L4 may be within a range between 40 mm and 80 mm, for example. On the other hand, the slot width W1 may be within a range between 3 mm and 40 mm, for example.

In addition, when the slow-wave plate 33 is made of quartz, a relationship between a thickness of the slow-wave plate 33 and radial positions of the first slots 32a and the second slots 32b (ratio L1/r and ratio L2/r) in the planar antenna plate 31 is preferably set as a wavelength of standing waves, in consideration of a reduction of the wavelength caused by a dielectric constant of the quartz and a periodicity of the standing waves in the quartz.

Next, there is described an example of a procedure of a plasma process using the plasma processing apparatus 100 in this embodiment. Herein, by using a gas containing oxygen as a process gas, a process for plasma oxidizing a wafer surface is described by way of example.

At first, a command is inputted from the user interface 52 so as to carry out a plasma oxidation process by the plasma processing apparatus 100, for example. Upon reception of the command, the process controller 51 reads out a recipe stored in the storage part 53. Then, control signals are sent from the process controller 51 to the respective end devices of the plasma processing apparatus 100, e.g., the gas introduction part 18, the exhaust apparatus 24, the electromagnetic-wave generator 39, and the heater power source 5a, such that the plasma oxidation process is performed under conditions based on the recipe.

Then, the gate valve 17 is opened, and a wafer W is loaded into the chamber 1 from the loading and unloading port 16. The wafer W is then placed on the stage 2. Following thereto, while the chamber 1 being exhausted and the pressure in the chamber 1 being reduced, an inert gas and an oxygen-containing gas are introduced into the chamber 1 at predetermined flow rates through the gas introduction part 15. Further, an exhaust amount and a gas supply amount are adjusted, such that the inside of the chamber 1 is adjusted to a predetermined pressure.

Thereafter, the electromagnetic-wave generator 39 is switched on, so as to generate electromagnetic waves (800 to 1000 MHz). Then, the electromagnetic waves having a frequency of, e.g., 915 MH, which is lower than the conventional microwave frequency, are introduced to the waveguide 37 through the matching circuit 38. The electromagnetic waves having been introduced into the waveguide 37 passes through the rectangular waveguide 37b and the coaxial waveguide 37a in this order so as to be supplied to the planar antenna plate 31 through the inner conductive member 41. The electromagnetic waves propagate in the rectangular waveguide 37b in the TE mode. The electromagnetic waves are converted by the mode converter 40 from the TE mode to the TEM mode, and propagate through the coaxial waveguide 37a toward the planar antenna plate 31. After that, the electromagnetic waves are radiated from the slots 32, which are holes formed in the planar antenna plate 31, toward the space above the wafer W in the chamber 1, through the transmission plate 28. In terms of efficiently supplying the electromagnetic waves (electromagnetic field), an output (electric power) of the electromagnetic waves is preferably set such that a power density per area 1 cm² of the planar antenna plate 31 is within a range between 0.41 W/cm² and 4.19 W/cm². The output of the electromagnetic waves can be selected from a range between, e.g., 500 W and 5000 W, such that the power density within the above range can be obtained depending on a purpose.

Due to the electromagnetic waves radiated from the planar antenna plate 31 into the chamber 1 through the transmission plate 28, an electromagnetic field can be uniformly formed in the chamber 1, whereby the inert gas and the oxygen-containing gas are respectively made into plasma states. Since the electromagnetic field is radiated from the many slots 32 in the planar antenna plate 31, the plasma excited by the electromagnetic field becomes a plasma having a plasma density of as high as 10⁹/cm³ to 10¹³/cm³ and an electron temperature as low as about 1.5 eV or below in the vicinity of the wafer W. The thus formed high-density plasma will less damage a base film by ions or the like. Thereafter, due to the action of active species such as radicals and ions in the plasma, the silicon surface of the wafer W is oxidized so that a thin film of silicon oxide, i.e., a SiO₂ film is formed. When a nitrogen gas is used in place of the oxygen-containing gas, a process for nitriding the silicon can be performed. Alternatively, with the use of a film-deposition material gas, a film deposition by a plasma CVD method can be performed.

When a control signal for finishing the plasma process is sent from the process controller 51, the electromagnetic-wave generator 39 is switched off, so that the plasma oxidation process is finished. Then, the supply of the process gas from the gas introduction part 18 is stopped, and the inside of the chamber is vacuumized. Thereafter, the wafer W is unloaded from the chamber 1. In this manner, the plasma process to the one wafer W is finished.

In the plasma processing apparatus 100, the slot pattern of the planar antenna plate 31 according to the present invention is made suitable for the electromagnetic waves generated by the electromagnetic-wave generator 39, which has a frequency within a range between the 800 MHz and 1000 MHz (preferably 915 MHz) that is lower than the conventional microwave frequency. By using electromagnetic waves for plasma generation having a frequency within a range between 800 MHz and 1000 MHz, a plasma density at which a surface wave plasma is cut off (cut-off density) is lowered, whereby a plasma can be stably, uniformly generated with a high power efficiency under a higher pressure condition, as compared with a case in which microwaves of the conventional frequency of 2.45 GHz are used.

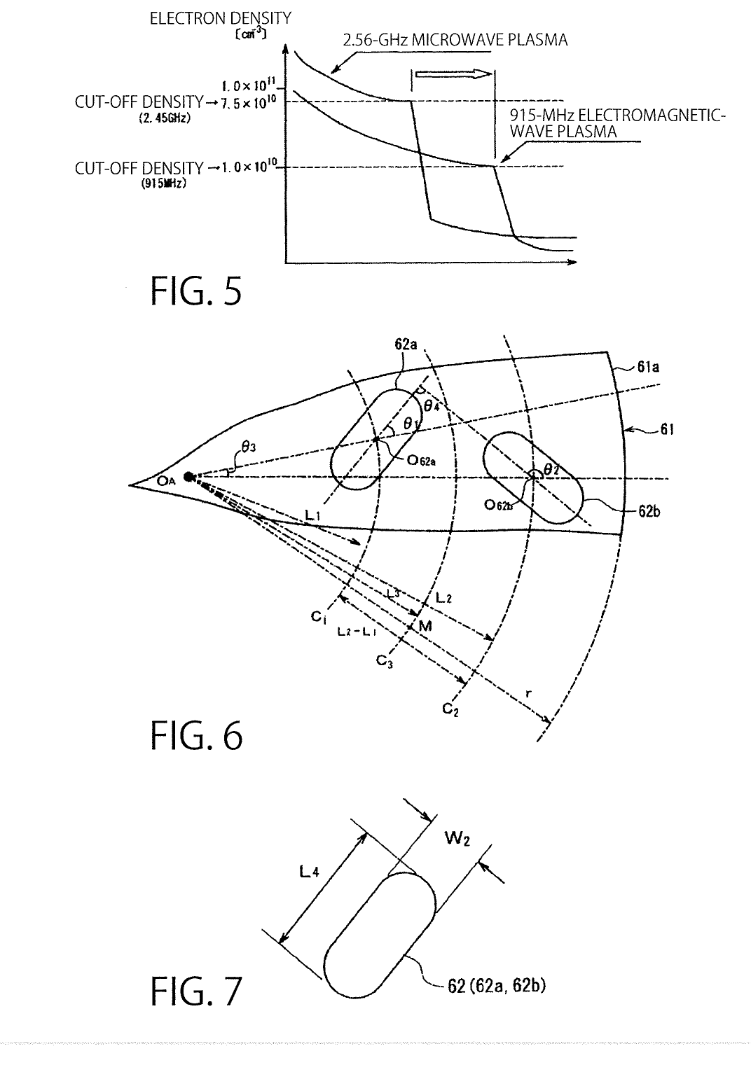

FIG. 5 shows a relationship between a process pressure and a plasma electron density in a plasma process carried out in the plasma processing apparatus 100. As the process pressure increases, the plasma electron density decreases. At the cut-off density, the electron density drastically decreases. The cut-off density of a 2.45-GHz microwave plasma is about 7.5×10¹⁰ cm⁻³, while the cut-off density of a 915-MHz electromagnetic-wave plasma is about 1.0×10¹⁰ cm⁻³. As shown in FIG. 5, as compared with the 2.45-GHz microwave plasma, the 915-MHz electromagnetic-wave plasma can maintain a plasma density equal to or greater than the cut-off density under the higher pressure condition.

In the planar antenna plate 31 in this embodiment, the ratio L1/r is within a range between 0.35 and 0.5, in which L1 is the distance from the center O_{A} of the planar antenna plate 31 to the center O₃₂ₐ of the inside first slot 32a, and r is the radius of the planar antenna plate 31. Simultaneously, the ratio L2/r is within a range between 0.7 and 0.85, in which L2 is the distance from the center O_{A} of the planar antenna plate 31 to the center O_{32b} of the outside second slot 32b, and r is the radius of the planar antenna plate 31. Thus, even when the frequency of the electromagnetic waves generated by the electromagnetic-wave generator 39 is within a range between 800 MHz and 1000 MHz, generation of reflected waves can be prevented, and the electromagnetic waves can be efficiently introduced into the chamber 1. Thus, a surface wave plasma can be stably maintained in the chamber.

In addition, in the planar antenna plate 31 in this embodiment, the angle θ1 defined by the longitudinal direction of the first slot 32a with respect to the straight line connecting the center O_{A} of the planar antenna plate 31 and the center O₃₂ₐ of the first slot 32a is within a range between 30° and 50°. Simultaneously, the angle θ2 defined by the longitudinal direction of the second 32b with respect to the straight line connecting the center O_{A} of the planar antenna plate 31 and the center O_{32b} of the second slot 32b is within a range between 130° and 150°. Further, the angle θ3 defined between the straight line connecting the center O_{A} of the planar antenna plate 31 and the center O₃₂ₐ of the first slot 32a, and the straight line connecting the center O_{A} of the planar antenna plate 31 and the center O_{32b} of the corresponding second slot 32b, is within a range between 8° and 15°. Furthermore, the angle θ4 defined between the longitudinal direction of the first slot 32a and the longitudinal direction of the corresponding second slot 32b is a substantially right angle, i.e., within a range between 85° and 95°. Since the angles θ1, θ2, θ3 and θ4 are specified within the aforementioned ranges, the electromagnetic waves can be introduced into the chamber 1 through the slots 32 with a high power efficiency, whereby a plasma can be suitably generated.

As described above, according to the planar antenna plate 31 in this embodiment, since the arrangement of the slots 32a and 32b is designed as described above, the electromagnetic waves having a frequency within a range between 800 MHz and 1000 MHz, which is lower than the conventional microwave frequency, can be efficiently introduced into the chamber 1. Thus, as compared with a case in which the conventional 2.45-GHz microwave are used, even under a higher pressure condition, the surface wave plasma can be uniformly, stably maintained in the chamber 1 of the plasma processing apparatus 100. Namely, by using this plasma processing apparatus 100, under a relatively higher pressure condition, improvement of a process rate and a process uniformity in a wafer plane can be achieved, whereby it is possible to realize a three-dimensional device process requiring a high precision, a micro-fabrication process, and a larger-diameter substrate process.

### Second Embodiment

Next, with reference to FIGS. 6 and 7, there will be described a planar antenna plate 61 in a second embodiment according to the present invention. FIG. 6 is a plan view showing a main part of the planar antenna plate 61 in the second embodiment, and FIG. 7 is an enlarged plan view showing a slot in the planar antenna plate 61. Similarly to the planar antenna plate 31 in the first embodiment, the planar antenna plate 61 in this embodiment is used in the plasma processing apparatus 100.

The planar antenna plate 61 has a base member 61a of a circular plate shape, and a lot of pairs of slots 62 (62a and 62b) formed in the base member 61a with a predetermined pattern. The planar antenna plate 61 has the same structure as that of the planar antenna plate 31 in the first embodiment, excluding that a width W2 of each slot 62 is larger and that the number of the slots 62 is smaller. Thus, in the following description, the differences from the first embodiment are principally described. The identical components are represented by the same reference numerals, and detailed description thereof is omitted.

Each slot 62 formed in the base member 61a has a somewhat larger width and an elongated shape. The slots 62 include a plurality of first slots 62a which are circumferentially arranged on positions near to a center O_{A} of the planar antenna plate 61, and a plurality of second slots 62b which are arranged outside the first slots 62a so as to surround the same. The first slots 62a and the second slots 62b are concentrically arranged.

A first slot 62a and a corresponding second slot 62b form a pair, and eight first slots 62a and eight second slots 62b are concentrically arranged at respective regular intervals in the planar antenna plate 61. A ratio L1/r is within a range between 0.35 and 0.5, in which L1 is a distance from the center O_{A} of the planar antenna plate 61 (which is the same as the center of the base member 61a) to a center O₆₂ₐ a of one of the first slots 62a, and r is a radius of the planar antenna plate 61. In addition, a ratio L2/r is within a range between 0.7 and 0.85, in which L2 is a distance from the center O_{A} of the planar antenna plate 61 to the center O_{62b} of one of the second slots 62b, and r is the radius of the planar antenna plate 61. The reason for specifying the ratios L1/r and L2/r within the above ranges is similar to that of the first embodiment.

Then, the following circles C1 to C3 are supposed. Namely, the circle C1 is concentric with the planar antenna plate 61 and passes the centers O₆₂ₐ of the first slots 62a, with a radius of the circle C1 being the distance L1. The circle C2 is concentric with the planar antenna plate 61 and passes the centers O_{62b} of the second slots 62b, with a radius of the circle C2 being the distance L2. The circle C3 is concentric with the planar antenna plate 61, and has a radius which is a distance L3 extending from the center O_{A} of the planar antenna plate 61 to radial mid-points M between circumferences of the circles C1 and C2. In this case, a ratio L3/r is preferably within a range between 0.5 and 0.7, in which L3 is the above-described distance and r is the radius of the planar antenna plate 61. By specifying the ratio L3/r within the above range, generation of reflected waves can be restrained, and the electromagnetic waves can be efficiently introduced from the slots so as to generate a stable plasma in the chamber 1.

In addition, it is preferable that a ratio (L2−L1)/r is within a range between 0.2 and 0.5, in which (L2−L1) is a difference between the distance L2 and the distance L1, and r is the radius of the planar antenna plate 61. By specifying the ratio (L2−L1)/r within the above range, generation of reflected waves can be restrained, and the electromagnetic waves can be efficiently introduced from the slots so as to uniformly generate a stable plasma in the chamber 1.

The ranges (and the reasons therefor) of the angles θ1, θ2, θ3 and θ4 shown in FIG. 6 are same as those of the first embodiment.

As shown in FIG. 7, a length of each first slot 62a and a length of each second slot 62b are the same with each other (slot length L4). In addition, a width of each first slot 62a and a width of each second slot 62b are the same with each other (slot width W2). A ratio (L4/W2) between the slot length and the slot width is preferable within a range between 1 and 26, in terms of improving a radiation efficiency (power efficiency) of the electromagnetic waves from the respective slots in the planar antenna plate 61. The slot length L4 may be within a range between 40 mm and 80 mm, for example, and the slot width W2 may be within a range between 3 mm and 40 mm, for example. In this embodiment, as compared with the planar antenna plate 31 in the first embodiment, a ratio of the slot width W2 is set larger. Thus, an area of the opening of each slot 62 is enlarged, whereby the electromagnetic waves can be efficiently introduced into the chamber 1 through the slots 62 in the planar antenna plate 61.

The other structures, operations and effects in this embodiment are the same as those of the first embodiment.

### Third Embodiment

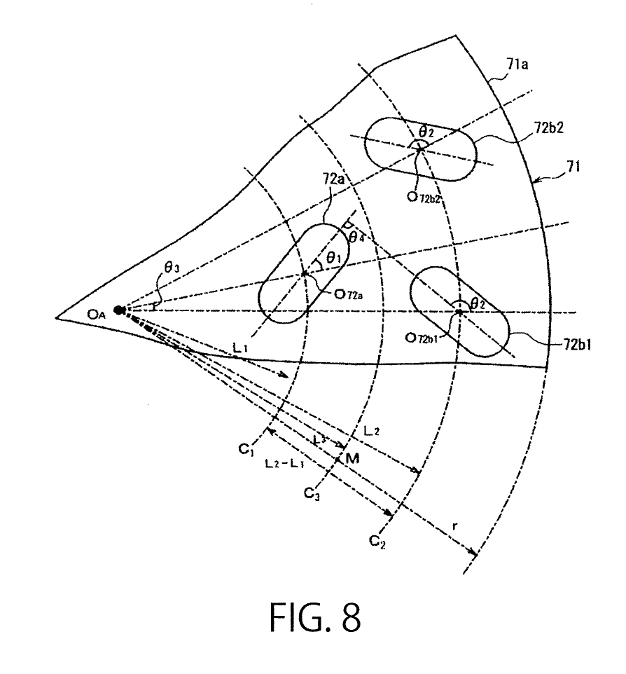

Next, there will be described a planar antenna plate 71 in a third embodiment according to the present invention with reference to FIG. 8. FIG. 8 is a plan view showing a main part of the planar antenna plate 71 in the third embodiment. Similarly to the planar antenna plate 31 in the first embodiment, the planar antenna plate 71 in this embodiment is used in the plasma processing apparatus 100. The planar antenna plate 71 has the same structure as that of the planar antenna plate 61 in the second embodiment, excluding that the number of the slots arranged on the outer circumferential side is larger. Thus, in the following description, the differences from the second embodiment are principally described. The identical components are represented by the same reference numerals, and detailed description thereof is omitted.

The planar antenna plate 71 includes a base member 71 of a circular plate shape, and a lot of slots 72 (72a, 72b1, 72b2) formed in the base member 71a with a predetermined pattern. The slots 72 include a plurality of first slots 72a which are circumferentially arranged on positions near to a center O_{A} of the planar antenna plate 71, and a plurality of second slots 72b1 and a plurality of third slots 72b2 which are arranged outside the first slots 72a so as to surround the same.

The first slots 72a, the second slots 72b1, and the third slots 72b2 are concentrically arranged. A first slot 72a and a corresponding second slot 72b1 form a pair. On the other hand, the third slot 72b2 is not a counterpart of the first slot 72a. Eight first slots 72a are arranged at regular intervals in the circumferential direction of the planar antenna plate 71. Similarly, eight second slots 72b1, which are counterparts of the first slots 72a among the outside slots, are arranged at regular intervals in the circumferential direction of the planar antenna plate 71.

On the other hand, the eight second slots 72b1 and the eight third slots 72b2 are arranged at respective regular intervals in the circumferential direction of the planar antenna plate 71 (the total number of the second and third slots 72b1 and 72b2 is sixteen). The second slots 72b1 and the third slots 72b2 are alternately arranged. In the planar antenna plate 71, since the third slots 72b2 are arranged in addition to the second slots 72b1, areas of the openings in the planar antenna plate 71 are further enlarged as compared with those of the planar antenna plate 61 in the second embodiment. Thus, the electromagnetic waves can be more efficiently introduced into the chamber 1.

Also in the planar antenna plate 71 in this embodiment, a ratio L1/r is within a range between 0.35 and 0.5, in which L1 is a distance from a center O_{A} of the planar antenna plate 71 (which is the same as the center of the base member 71a) to a center O₇₂ₐ of one of the first slots 72a, and r is a radius of the planar antenna plate 71. In addition, a ratio L2/r is within a range between 0.7 and 0.85, in which L2 is a distance from the center O_{A} of the planar antenna plate 71 to a center O_{72b1} of one of the second slots 72b1 or a center O_{72b2} of one of the third slots 72b2, and r is the radius of the planar antenna plate 61. The reason for specifying the ratios L1/r and L2/r within the above ranges is similar to that of the first embodiment. By specifying the ratios within the above ranges, generation of reflected waves can be restrained, and the electromagnetic waves can be efficiently supplied into the chamber 1 so as to generate a stable plasma.

Then, the following circles C1 to C3 are supposed. Namely, the circle C1 is concentric with the planar antenna plate 71 and passes the centers O₇₂ₐ of the first slots 72a, with a radius of the circle C1 being the distance L1. The circle C2 is concentric with the planar antenna plate 71 and passes the centers O_{72b1} of the second slots 72b1, with a radius of the circle C2 being the distance L2. The circle C3 is concentric with the planar antenna plate 71, and has a radius which is a distance L3 extending from the center O_{A} of the planar antenna plate 61 to radial mid-points M between circumferences of the circles C1 and C2. In this case, a ratio L3/r is preferably within a range between 0.5 and 0.7, in which L3 is the above-described distance and r is the radius of the planar antenna plate 71. By specifying the ratio L3/r within the above range, generation of reflected waves can be restrained, and the electromagnetic waves can be efficiently supplied into the chamber 1 so as to generate a stable plasma.

In addition, it is preferable that a ratio (L2−L1)/r is within a range between 0.2 and 0.5, in which (L2−L1) is a difference between the distance L2 and the distance L1, and r is the radius of the planar antenna plate 71. By specifying the ratio (L2−L1)/r within the above range, generation of reflected waves can be restrained, and the electromagnetic waves can be efficiently supplied into the chamber 1 so as to generate a stable plasma.

The ranges (and the reasons therefor) of the angles θ1, θ2, θ3 and θ4 shown in FIG. 8 are same as those of the first embodiment.

Ranges of lengths and widths of the first slots 72a, the second slots 72b1 and the third slots 72b2, and the reasons therefor are the same as those of the second embodiment.

The other structures, operations and effects in this embodiment are the same as those of the first embodiment.

Although the embodiments of the present invention have been described above, the present invention is not limited thereto and can be variously modified. For example, the plasma processing apparatus 100 including the planar antenna plate 31 with the slot pattern according to the present invention can be applied to a plasma oxidizing apparatus, a plasma nitriding apparatus, a plasma CVD apparatus, a plasma etching apparatus, a plasma ashing apparatus, and so on. Further, although the plasma processing apparatus including the planar antenna plate according to the present invention is configured to process a semiconductor wafer as an object to be processed, the present invention can be applied to plasma processing apparatus configured to process a substrate for a flat panel display device such as a liquid crystal display device and an organic EL display device.

Furthermore, the planar shape of each slot is not limited to the above embodiments, and a circular shape, an oval shape, a square shape, and a rectangular shape can be employed.

1. A planar antenna member configured to introduce electromagnetic waves generated by an electromagnetic-wave generating source into a processing vessel of a plasma processing apparatus, the planar antenna member comprising:
a base member of a circular plate shape, made of a conductive material; and
a plurality of through-holes formed in the base member of a circular plate shape, the through-holes being configured to radiate the electromagnetic waves;
wherein:
the through-holes include a plurality of first through-holes which are arranged on a circumference of a circle whose center corresponds to a center of the planar antenna member, and a plurality of second through-holes which are arranged concentrically with the circle outside the first through-holes;
a ratio L1/r is within a range between 0.35 and 0.5, in which L1 is a distance from the center of the planar antenna member to a center of one of the first through-holes, and r is a radius of the planar antenna member; and
a ratio L2/r is within a range between 0.7 and 0.85, in which L2 is a distance from the center of the planar antenna member to a center of one of the second through-holes, and r is the radius of the planar antenna member.

2. The planar antenna member according to claim 1, wherein
when there are supposed the following first to third circles, i.e., a first circle passing the centers of the first through-holes with a radius of the first circle being the distance L1, a second circle passing the centers of the second through-holes with a radius of the second circle being the distance L2, and a third circle concentric with the first circle and the second circle, the third circle passing radial mid-points of a circumference of the first circle and a circumference of the second circle, a ratio L3/r is within a range between 0.5 and 0.7, in which L3 is a radius of the third circle and r is the radius of the planar antenna member.

3. The planar antenna member according to claim 1, wherein a ratio (L2−L1)/r is within a range between 0.2 and 0.5, in which (L2−L1) is a difference between the distance L2 and the distance L1, and r is the radius of the planar antenna plate.

4. The planar antenna member according to claim 1, wherein
each of the first through-holes and the second through-holes has an elongated shape, and an angle defined by a longitudinal direction of a second through-hole with respect to a longitudinal direction of a corresponding first through-hole is within a range between 85° and 95°.

5. The planar antenna member according to claim 4, wherein
an angle defined by a longitudinal direction of a first through-hole with respect to a straight line connecting the center of the planar antenna member and the center of the first through-hole is within a range between 30° and 50°.

6. The planar antenna member according to claim 4, wherein
an angle defined by a longitudinal direction of a second through-hole with respect to a straight line connecting the center of the planar antenna member and the center of the second through-hole is within a range between 130° and 150°.

7. The planar antenna member according to claim 1, wherein
an angle defined between a straight line connecting the center of the planar antenna member and the center of a first through-hole, and a straight line connecting the center of the planar antenna member and the center of a corresponding second through-hole, is within a range between 8° and 15°.

8. The planar antenna member according to claim 1, wherein
a frequency of the electromagnetic waves generated by the electromagnetic-wave generating source is within a range between 800 MHz and 1000 MHz.

9. A plasma processing apparatus comprising:
a processing vessel configured to contain an object to be processed, the processing vessel being capable of creating a vacuum therein;
a gas introduction part configured to supply a gas into the processing vessel;
an exhaust apparatus configured to exhaust the processing vessel to reduce a pressure in the processing vessel;
a transmission plate hermetically fitted in an upper opening of the processing vessel, the transmission plate being capable of transmitting therethrough electromagnetic waves for generating a plasma into the processing vessel;
a planar antenna member disposed above the transmission plate, the planar antenna member being configured to introduce the electromagnetic waves into the processing vessel;
a cover member configured to cover the planar antenna member from above; and
a waveguide disposed to pass through the cover member, the waveguide being configured to supply the planar antenna member with the electromagnetic waves within a range between 800 MHz and 1000 MHz, which are generated by an electromagnetic-wave generating source;
wherein
the planar antenna member includes: a planar antenna member configured to introduce electromagnetic waves generated by an electromagnetic-wave generating source into a processing vessel of a plasma processing apparatus, the planar antenna member comprising:
a base member of a circular plate shape, made of a conductive material; and
a plurality of through-holes formed in the base member of a circular plate shape, the through-holes being configured to radiate the electromagnetic waves;
wherein:
the through-holes include a plurality of first through-holes which are arranged on a circumference of a circle whose center corresponds to a center of the planar antenna member, and a plurality of second through-holes which are arranged concentrically with the circle outside the first through-holes;
a ratio L1/r is within a range between 0.35 and 0.5, in which L1 is a distance from the center of the planar antenna member to a center of one of the first through-holes, and r is a radius of the planar antenna member; and
a ratio L2/r is within a range between 0.7 and 0.85, in which L2 is a distance from the center of the planar antenna member to a center of one of the second through-holes, and r is the radius of the planar antenna member.

10. The plasma processing apparatus according to claim 9, wherein
when there are supposed the following first to third circles, i.e., a first circle passing the centers of the first through-holes with a radius of the first circle being the distance L1, a second circle passing the centers of the second through-holes with a radius of the second circle being the distance L2, and a third circle concentric with the first circle and the second circle, the third circle passing radial mid-points of a circumference of the first circle and a circumference of the second circle, a ratio L3/r is within a range between 0.5 and 0.7, in which L3 is a radius of the third circle and r is the radius of the planar antenna member.

11. The plasma processing apparatus according to claim 9, wherein
a ratio (L2−L1)/r is within a range between 0.2 and 0.5, in which (L2−L1) is a difference between the distance L2 and the distance L1, and r is the radius of the planar antenna plate.

12. The plasma processing apparatus according to claim 9, wherein
each of the first through-holes and the second through-holes has an elongated shape, and an angle defined by a longitudinal direction of a second through-hole with respect to a longitudinal direction of a corresponding first through-hole is within a range between 85° and 95°.

13. The plasma processing apparatus according to claim 12, wherein
an angle defined by a longitudinal direction of a first through-hole with respect to a straight line connecting the center of the planar antenna member and the center of the first through-hole is within a range between 30° and 50°.

14. The plasma processing apparatus according to claim 12, wherein
an angle defined by a longitudinal direction of a second through-hole with respect to a straight line connecting the center of the planar antenna member and the center of the second through-hole is within a range between 130° and 150°.

15. The plasma processing apparatus according to claim 9, wherein
an angle defined between a straight line connecting the center of the planar antenna member and the center of a first through-hole, and a straight line connecting the center of the planar antenna member and the center of a corresponding second through-hole, is within a range between 8° and 15°.
